(19) United States
(12) Patent Application Publication
(10) Pub. No.: US 2025/0012862 A1
(43) Pub. Date: Jan. 9, 2025

(54) BATTERY CAPACITY PREDICTION APPARATUS AND OPERATING METHOD THEREOF

(71) Applicant: LG ENERGY SOLUTION, LTD., Seoul (KR)

(72) Inventor: Jung Hwan CHOI, Daejeon (KR)

(73) Assignee: LG ENERGY SOLUTION, LTD., Seoul (KR)

(21) Appl. No.: 18/710,610

(22) PCT Filed: Dec. 19, 2022
(86) PCT No.: PCT/KR2022/020745

§ 371 Date: May 15, 2024

(30) Foreign Application Priority Data
Jan. 7, 2022 (KR) 10-2022-0003018

(51) Int. Cl. G01R 31/382; G01R 31/374

(52) U.S. Cl. CPC G01R 31/382; G01R 31/374

(57) ABSTRACT

A battery capacity prediction apparatus according to an example embodiment disclosed herein includes an extraction unit configured to extract comparison data obtained by comparing a measured capacity of a battery with a reference capacity of the battery and extract capacity change data obtained by measuring a capacity change of the battery with respect to a cycle change of the battery and a controller configured to predict a capacity of the battery based on the comparison data and the capacity change data.

### CROSS-REFERENCE TO RELATED APPLICATION

This application claims priority to and the benefit of Korean Patent Application No. 10-2022-0003018, filed in the Korean Intellectual Property Office on Jan. 7, 2022, the entire contents of which are incorporated herein by reference.

### TECHNICAL FIELD

Example embodiments disclosed herein relate to a battery capacity prediction apparatus and an operating method thereof.

### BACKGROUND ART

An electric vehicle is supplied with electricity from an external source to charge a battery cell, and then a motor is driven by a voltage charged in the battery cell to obtain power. The battery cell of the electric vehicle may have heat generated therein by chemical reaction occurring in a process of charging and discharging electricity, and the heat may impair performance and lifetime of the battery cell.

As battery cells are repeatedly used and charged and discharged, they age, their lifespans are gradually shortened, and their capacities decrease. The decrease in a capacity of a battery cell may vary depending on use temperature, charge current, discharge current, and discharge depth of the battery cell, and the capacity of the battery cell may rapidly decrease depending on the decreasing amount of a positive electrode material or a negative electrode material and lithium ions inside the battery cell. When the capacity of a battery cell rapidly decreases, it may lead to a decrease in available battery energy, which reduces the effectiveness of a battery and deteriorates the stability of the battery.

### DISCLOSURE

### Technical Objective

Example embodiments disclosed herein aim to provide a battery capacity prediction apparatus and an operating method thereof in which a decrease in a capacity of a battery in various temperature, current, and voltage sections may be analyzed to diagnose a rapid capacity decrease of the battery in advance.

Technical objects of the example embodiments disclosed herein are not limited to the above-described technical objects, and other unmentioned technical objects would be clearly understood by one of ordinary skill in the art from the following description.

### Technical Solution

A battery capacity prediction apparatus according to an example embodiment disclosed herein includes an extraction unit configured to extract comparison data obtained by comparing a measured capacity of a battery with a reference capacity of the battery and extract capacity change data obtained by measuring a capacity change of the battery with respect to a cycle change of the battery and a controller configured to predict a capacity of the battery based on the comparison data and the capacity change data.

According to an example embodiment, the extraction unit may be further configured to extract a comparison value obtained by comparing the measured capacity of the battery with the reference capacity of the battery, measured through a reference performance test (RPT).

According to an example embodiment, the extraction unit may be further configured to measure a change of the comparison value with respect to a temperature change of the battery or a change of the comparison value with respect to a current change of the battery.

According to an example embodiment, the controller may be further configured to predict a capacity of the battery under reference performance test conditions based on the capacity change data and the comparison value.

According to an example embodiment, the controller may be further configured to predict the capacity of the battery under full equivalent cycle (FEC) conditions by converting the reference capacity into a nominal capacity of the battery.

According to an example embodiment, the controller may be further configured to extract a capacity change pattern of the battery based on the capacity of the battery under the full equivalent cycle conditions.

According to an example embodiment, the controller may be further configured to analyze a capacity change pattern immediately after the reference performance test, a normal capacity change pattern, and a rapid capacity deterioration pattern by extracting the capacity change pattern of the battery.

An operating method of a battery capacity prediction apparatus according to an example embodiment disclosed herein includes extracting comparison data by comparing a measured capacity of a battery with a reference capacity of the battery, measuring a capacity change of the battery with respect to a cycle change of the battery, and predicting a capacity of the battery based on the comparison data and capacity change data.

According to an example embodiment, the extracting of the comparison data by comparing the measured capacity of the battery with the reference capacity of the battery may include extracting a comparison value obtained by comparing the measured capacity of the battery with the reference capacity of the battery, measured through a reference performance test (RPT).

According to an example embodiment, the extracting of the comparison data by comparing the measured capacity of the battery with the reference capacity of the battery may include measuring a change of the comparison value with respect to a temperature change of the battery or a change of the comparison value with respect to a current change of the battery.

According to an example embodiment, the predicting of the capacity of the battery based on the comparison data and capacity change data may include predicting a capacity of the battery under reference performance test conditions based on the capacity change data and the comparison value.

According to an example embodiment, the predicting of the capacity of the battery based on the comparison data and capacity change data may include predicting the capacity of the battery under full equivalent cycle (FEC) conditions by converting the reference capacity into a nominal capacity of the battery.

According to an example embodiment, the predicting of the capacity of the battery based on the comparison data and capacity change data may include extracting a capacity change pattern of the battery based on the capacity of the battery under the full equivalent cycle conditions.

According to an example embodiment, the predicting of the capacity of the battery based on the comparison data and capacity change data may include analyzing a capacity change pattern immediately after the reference performance test, a normal capacity change pattern, and a rapid capacity deterioration pattern by extracting the capacity change pattern of the battery.

### Advantageous Effects

With a battery capacity prediction apparatus and an operating method thereof according to an example embodiment disclosed herein, a capacity decrease of a battery in various temperature, current, and voltage sections may be analyzed to diagnose a rapid capacity decrease of the battery in advance.

### BRIEF DESCRIPTION OF DRAWINGS

FIG. 1 illustrates a battery pack according to an example embodiment disclosed herein.

FIG. 2 is a block diagram showing a configuration of a battery capacity prediction apparatus, according to an example embodiment disclosed herein.

FIG. 3 is a graph showing capacity data change of a battery and reference capacity data change with respect to cycle change of the battery, according to an example embodiment disclosed herein.

FIG. 4A is a graph showing comparison value change with respect to temperature change of a battery, according to an example embodiment disclosed herein.

FIG. 4B is a graph showing comparison value change with respect to current change of a battery, according to an example embodiment disclosed herein.

FIG. 5 is a graph showing change in capacity deterioration amount per cycle of a battery with respect to cycle change of the battery, according to an example embodiment disclosed herein.

FIG. 6A is a graph showing a capacity change pattern of a battery with respect to a full equivalent cycle change of the battery, according to an example embodiment disclosed herein.

FIG. 6B is a graph showing a capacity change of a battery with respect to a full equivalent cycle change of the battery, according to an example embodiment disclosed herein.

FIG. 7 is a flowchart of an operating method of a battery capacity prediction apparatus according to an example embodiment disclosed herein.

FIG. 8 is a block diagram showing a hardware configuration of a computing system for implementing a battery capacity prediction apparatus according to an example embodiment disclosed herein.

### MODES FOR PRACTICING INVENTION

Hereinafter, some example embodiments disclosed in this document will be described in detail with reference to the example drawings. In adding reference numerals to components of each drawing, it should be noted that the same components are given the same reference numerals even though they are indicated in different drawings. In addition, in describing the example embodiments disclosed in this document, when it is determined that a detailed description of a related known configuration or function interferes with the understanding of an example embodiment disclosed in this document, the detailed description thereof will be omitted.

To describe a component of an example embodiment disclosed herein, terms such as first, second, A, B, (a), (b), etc., may be used. These terms are used merely for distinguishing one component from another component and do not limit the component to the essence, sequence, order, etc., of the component. The terms used herein, including technical and scientific terms, have the same meanings as terms that are generally understood by those skilled in the art, as long as the terms are not differently defined. Generally, the terms defined in a generally used dictionary should be interpreted as having the same meanings as the contextual meanings of the relevant technology and should not be interpreted as having ideal or exaggerated meanings unless they are clearly defined in the present document.

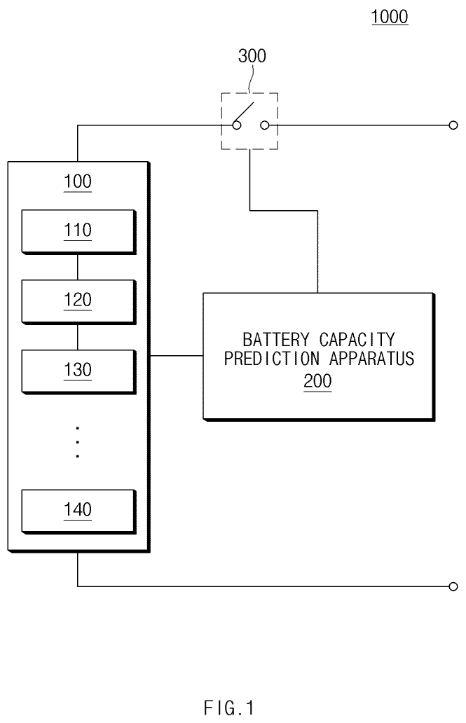

FIG. 1 illustrates a battery pack according to an example embodiment disclosed herein.

With reference to FIG. 1, a battery pack 1000 according to an example embodiment disclosed herein may include a battery module 100, a battery capacity prediction apparatus 200, and a relay 300.

The battery module 100 may include a plurality of battery cells 110, 120, 130, and 140. Although the plurality of battery cells are illustrated as four in FIG. 1, the present disclosure is not limited thereto, and the battery module 100 may include n battery cells (n is a natural number equal to or greater than 2).

The battery module 100 may supply power to a target device (not shown). To this end, the battery module 100 may be electrically connected to the target device. Herein, the target device may include an electrical, electronic, or mechanical device that operates by receiving power from the battery pack 1000 including the plurality of battery cells 110, 120, 130, and 140, and the target device may be, for example, an electric vehicle (EV) or an energy storage system (ESS), but is not limited thereto.

The plurality of battery cells 110, 120, 130, and 140, each of which is a basic unit of a battery available by charging and discharging electrical energy, may be a lithium ion (Li-ion) battery, an Li-ion polymer battery, a nickel-cadmium (Ni—Cd) battery, a nickel hydrogen (Ni-MH) battery, etc., and are not limited thereto. Meanwhile, although one battery module 100 is illustrated in FIG. 1, the battery module 100 may be configured in plural according to an example embodiment.

The battery capacity prediction apparatus 200 may predict a capacity of the plurality of battery cells 110, 120, 130, and 140 based on temperature, current, and voltage data of the plurality of battery cells 110, 120, 130, and 140. The battery capacity prediction apparatus 200 may predict the capacity of the plurality of battery cells 110, 120, 130, and 140 for each of temperature, current, and voltage of a battery based on battery data of the plurality of battery cells 110, 120, 130, and 140.

According to an example embodiment, the battery capacity prediction apparatus 200 may be implemented in the form of a battery management system (BMS). Moreover, according to an example embodiment, the battery capacity prediction apparatus 200 may be mounted on a battery management system.

Here, the battery management system may manage and/or control a state and/or an operation of the battery module 100. For example, the battery management system may manage and/or control the states and/or operations of the plurality of battery cells 110, 120, 130, and 140 included in the battery module 100. The battery management system may manage charge and/or discharge of the battery module 100.

In addition, the battery management system may monitor voltage, current, temperature, etc., of the battery module 100 and/or each of the plurality of battery cells 110, 120, 130, and 140 included in the battery module 100. A sensor or various measurement modules for monitoring performed by the battery management system, which are not shown, may be additionally installed in the battery module 100, a charging/discharging path, any position of the battery module 100, etc. The battery management system may calculate a parameter indicating a state of the battery module 100, e.g., a state of charge (SoC), a state of health (SoH) etc., based on a measurement value such as monitored voltage, current, temperature, etc.

The battery management system may control an operation of the relay 300. For example, the battery management system may short-circuit the relay 300 to supply power to the target device. The battery management system may short-circuit the relay 300 when a charging device is connected to the battery pack 1000.

The battery management system may calculate a cell balancing time of each of the plurality of battery cells 110, 120, 130, and 140. Here, the cell balancing time may be defined as a time required for balancing of the battery cell. For example, the battery management system may calculate a cell balancing time based on an SoC, a battery capacity, and a balancing efficiency of each of the plurality of battery cells 110, 120, 130, and 140.

Hereinbelow, a configuration and an operation of the battery capacity prediction apparatus 200 will be described in detail.

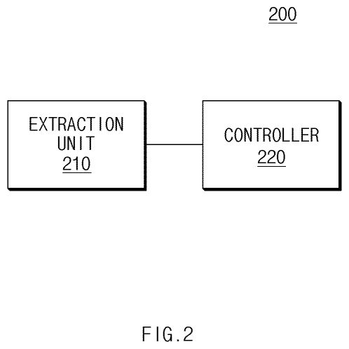

FIG. 2 is a block diagram showing a configuration of a battery capacity prediction apparatus, according to an example embodiment disclosed herein.

Hereinbelow, a configuration of the battery capacity prediction apparatus 200 will be described with reference to FIG. 2.

First, with reference to FIG. 2, the battery capacity prediction apparatus 200 may include an extraction unit 210 and a controller 220.

The extraction unit 210 may obtain capacity data C obtained by measuring the capacity of the plurality of battery cells 110, 120, 130, and 140.

The extraction unit 210 may obtain reference capacity data (C_{RPT}) obtained by measuring a reference capacity of the plurality of battery cells 110, 120, 130, and 140. Here, a reference capacity may refer to a capacity of a battery, measured through a reference performance test (RPT). The reference performance test may periodically measure a lifespan or a capacity of a battery under specific temperature, specific current, and specific voltage range conditions to identify deteriorating performance of the target device. According to an example embodiment, the reference performance test may repeat charge and discharge under specific temperature and specific current conditions until the battery reaches a voltage with an SoC of 100% from a voltage with an SoC of 0%.

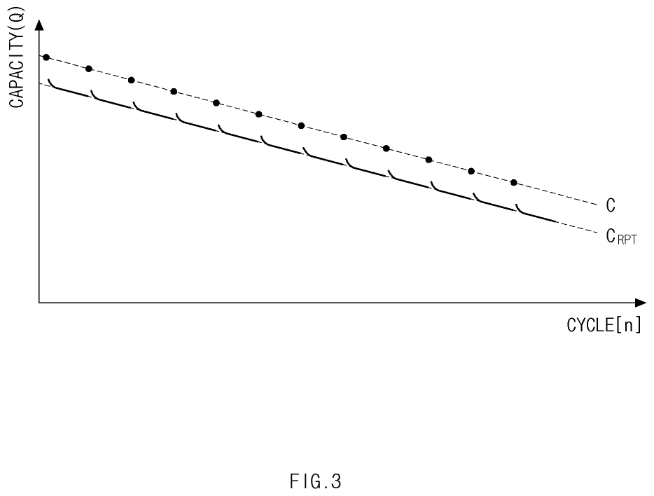

FIG. 3 is a graph showing capacity data change of a battery and reference capacity data change with respect to cycle change of the battery, according to an example embodiment disclosed herein. With reference to FIG. 3, the extraction unit 210 may compare reference capacity data (C_{RPT}) of the plurality of battery cells 110, 120, 130, and 140 with measured capacity data C of the plurality of battery cells 110, 120, 130, and 140 to extract comparison data of comparing a measured capacity C of the plurality of battery cells 110, 120, 130, and 140 with a reference capacity (C_{RPT}) of the plurality of battery cells 110, 120, 130, and 140. More specifically, the extraction unit 210 may extract a comparison value (C/C_{RPT}) of comparing the measured capacity C of the plurality of battery cells 110, 120, 130, and 140 with the reference capacity (C_{RPT}) of the plurality of battery cells 110, 120, 130, and 140.

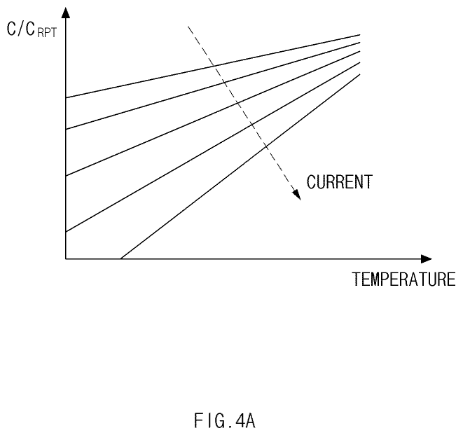

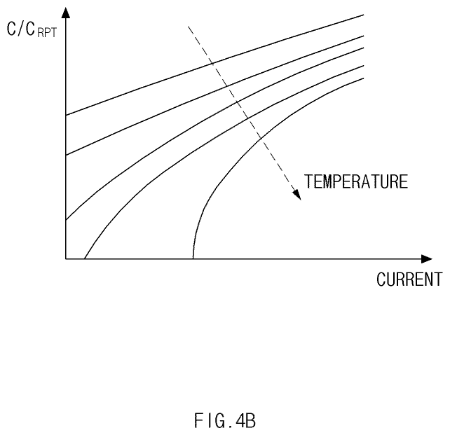

FIG. 4A is a graph showing comparison value change with respect to temperature change of a battery, according to an example embodiment disclosed herein. FIG. 4B is a graph showing comparison value change with respect to current change of a battery, according to an example embodiment disclosed herein.

With reference to FIGS. 4A and 4B, the extraction unit 210 may generate a graph showing comparison value change with respect to temperature change of the plurality of battery cells 110, 120, 130, and 140. The extraction unit 210 may generate a graph showing change in comparison value (C/C_{RPT}) with respect to current of the plurality of battery cells 110, 120, 130, and 140. The extraction unit 210 may analyze change in comparison value (C/C_{RPT}) with respect to temperature change of the plurality of battery cells 110, 120, 130, and 140 or current change of the plurality of battery cells 110, 120, 130, and 140 to measure a trend of change in comparison value (C/C_{RPT}) with respect to temperature change of the plurality of battery cells 110, 120, 130, and 140 or a trend of change in comparison value (C/C_{RPT}) with respect to current change of the battery.

The extraction unit 210 may measure a capacity change amount per cycle of the plurality of battery cells 110, 120, 130, and 140 with respect to cycle change of the plurality of battery cells 110, 120, 130, and 140. That is, the extraction unit 210 may measure a capacity deterioration amount per cycle (ΔC) of the plurality of battery cells 110, 120, 130, and 140 with respect to cycle change of the plurality of battery cells 110, 120, 130, and 140.

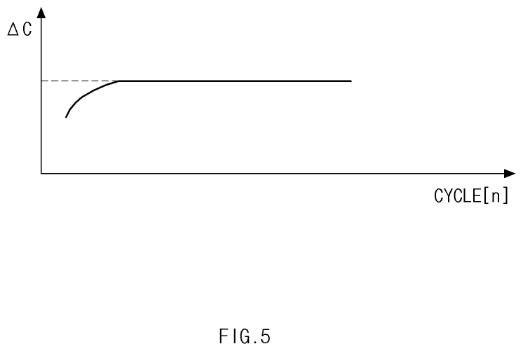

FIG. 5 is a graph showing change in capacity deterioration amount per cycle of a battery with respect to cycle change of the battery, according to an example embodiment disclosed herein. With reference to FIG. 5, the extraction unit 210 may extract capacity change data obtained by measuring a capacity change per cycle of a battery with respect to cycle change of the plurality of battery cells 110, 120, 130, and 140. For example, when a capacity for n cycle repetitions of the plurality of battery cells 110, 120, 130, and 140 is defined as Cₙ, and a capacity of the plurality of battery cells 110, 120, 130, and 140 before k cycles is defined as Cₙ₋ₖ, a capacity deterioration amount defined per cycle ΔC=Cₙ=Cₙ−Cₙ₋ₖ of the plurality of battery cells 110, 120, 130, and 140 may be calculated.

The extraction unit 210 may extract capacity change data indicating change in capacity deterioration amount per cycle (Cₙ) of the plurality of battery cells 110, 120, 130, and 140 with respect to cycle change of the plurality of battery cells 110, 120, 130, and 140.

The controller 220 may predict the capacity of the plurality of battery cells 110, 120, 130, and 140 based on comparison data and capacity change data. More specifically, the controller 220 may predict capacity change of the plurality of battery cells 110, 120, 130, and 140 under reference performance test conditions based on capacity change data and a comparison value.

The controller 220 may multiply a reciprocal (C_{RPT}/C) of the comparison value to the capacity deterioration amount defined per cycle (ΔC) of the plurality of battery cells 110, 120, 130, and 140 to calculate

$$Δ C \times \frac{{C}_{RPT}}{C}$$

as a capacity change rate of the plurality of battery cells 110, 120, 130, and 140 under reference performance test conditions.

The controller 220 may convert a reference capacity of the plurality of battery cells into a nominal capacity of the plurality of battery cells based on the predicted capacity of the plurality of battery cells 110, 120, 130, and 140 under the reference performance test conditions to predict the capacity of the plurality of battery cells under full equivalent cycle (FEC) conditions.

The controller 220 may multiply a value (Cₙₒₘᵢₙₐₗ/C) obtained by comparing the nominal capacity (Cₙₒₘᵢₙₐₗ) of the battery cells 110, 120, 130, and 140 with the measured capacity C of the plurality of battery cells 110, 120, 130, and 140 to the capacity deterioration amount per cycle (ΔC) of the plurality of battery cells 110, 120, 130, and 140 under the reference performance test conditions to calculate the capacity deterioration amount ((ΔC)_{FEC}) of the plurality of battery cells 110, 120, 130, and 140 under the FEC conditions.

$${( Δ C )}_{FEC} = ( {C}_{n} - {C}_{n - k} ) \times \frac{{C}_{nominal}}{C} / k = Δ C \times \frac{{C}_{nominal}}{C} / k$$

Here, the controller 220 may select a multiple of the value k to increase a value of the small capacity deterioration amount ((ΔC)_{FEC}) of the plurality of battery cells 110, 120, 130, and 140.

The controller 220 may extract the capacity change pattern of the battery based on the capacity of the battery under the full equivalent cycle conditions.

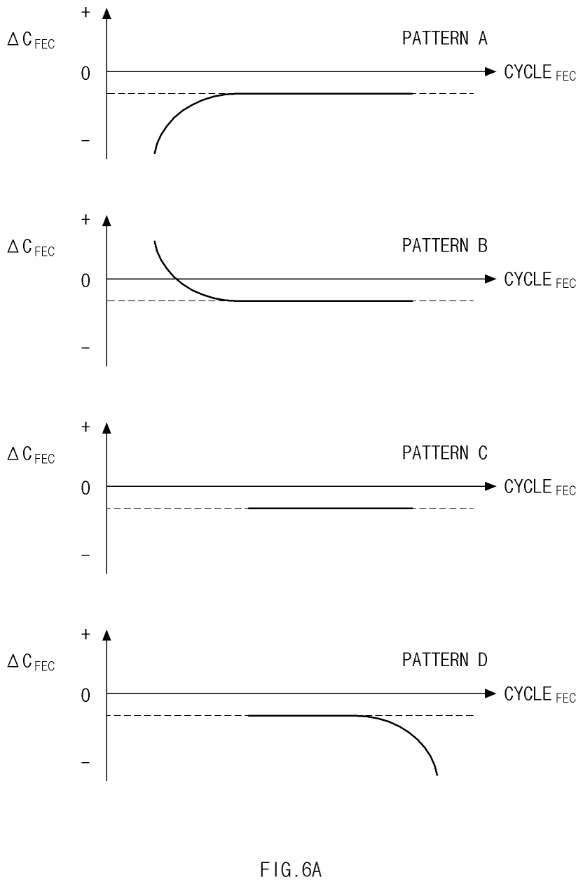

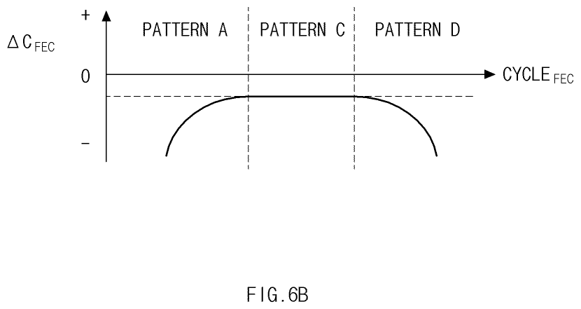

FIG. 6A is a graph showing a capacity change pattern of a battery with respect to a full equivalent cycle change of the battery, according to an example embodiment disclosed herein. With reference to FIG. 6A, more specifically, the controller 220 may calculate a graph showing change in capacity deterioration amount (ΔC_{FEC}) of the plurality of battery cells 110, 120, 130, and 140 under the FEC conditions.

The controller 220 may extract and analyze a pattern A, a pattern B, a pattern C, and a pattern D that are various capacity change patterns of the plurality of battery cells 110, 120, 130, and 140.

In FIG. 6A, the pattern A calculated by the controller 220, which is a pattern appearing when the deterioration speed of the plurality of battery cells 110, 120, 130, and 140 decreases, may appear in a battery cycle immediately after the reference performance test of the plurality of battery cells 110, 120, 130, and 140. The controller 220 may analyze the pattern A as a capacity change pattern appearing as temperatures or currents of the plurality of battery cells 110, 120, 130, and 140 are different.

In FIG. 6A, the pattern A calculated by the controller 220 may be analyzed as a pattern appearing when the deterioration speed of the plurality of battery cells 110, 120, 130, and 140 is constant. The controller 220 may analyze the pattern C as a capacity change pattern appearing when a loss of an active material (LAM) of the plurality of battery cells 110, 120, 130, and 140 linearly deteriorates.

In FIG. 6A, the pattern D calculated by the controller 220 may be analyzed as a pattern appearing when the deterioration speed of the plurality of battery cells 110, 120, 130, and 140 is accelerated. The controller 220 may analyze the pattern D as a pattern appearing when the capacity of the plurality of battery cells 110, 120, 130, and 140 exponentially decreases due to lithium plating or rapid reduction of an electrolyte of the plurality of battery cells 110, 120, 130, and 140.

FIG. 6B is a graph showing a capacity change of a battery with respect to a full equivalent cycle change of the battery, according to an example embodiment disclosed herein. The controller 220 may extract a graph showing a capacity change of a battery with respect to a full equivalent cycle change of the battery by collecting various capacity change patterns of the battery with respect to a full equivalent cycle change of the battery shown in FIG. 6A.

The controller 220 may analyze a capacity change pattern of the plurality of battery cells 110, 120, 130, and 140 immediately after a reference performance test, a normal capacity change pattern of the plurality of battery cells 110, 120, 130, and 140, and a rapid capacity deterioration pattern of the plurality of battery cells 110, 120, 130, and 140, based on FIG. 6B.

As described above, with the battery capacity prediction apparatus 200 according to an example embodiment disclosed herein, a capacity decrease of a battery in various temperature, current, and voltage sections may be analyzed to diagnose a rapid capacity decrease of the battery in advance.

In addition, the battery capacity prediction apparatus 200 may improve the efficiency and stability of battery management by accurately diagnosing rapid deterioration of the capacity of the battery in advance. Moreover, the battery capacity prediction apparatus 200 may define a relationship between the reference capacity of the battery measured through a reference performance test and a deterioration cycle of the battery to extract a capacity change pattern of the battery.

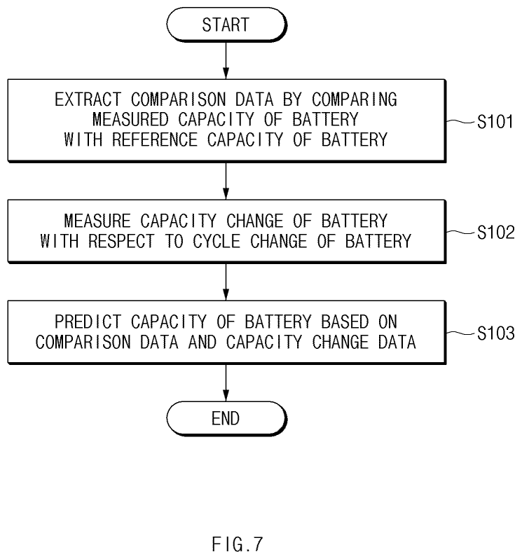

FIG. 7 is a flowchart of an operating method of a battery capacity prediction apparatus according to an example embodiment disclosed herein.

Hereinbelow, with reference to FIGS. 1 to 6, an operating method of the battery capacity prediction apparatus 200 will be described.

The battery capacity prediction apparatus 200 may be substantially the same as the battery capacity prediction apparatus 200 described with reference to FIGS. 1 to 6, and thus will be briefly described to avoid redundant description.

With reference to FIG. 7, an operating method of the battery capacity prediction apparatus 200 may include operation S101 of comparing a measured capacity of a battery with a reference capacity of the battery to extract comparison data, operation S102 of measuring a capacity change of the battery with respect to a cycle change of the battery, and operation S103 of predicting a capacity of the battery based on the comparison data and capacity change data.

In operation S101, the extraction unit 210 may obtain reference capacity data (C_{RPT}) obtained by measuring a reference capacity of the plurality of battery cells 110, 120, 130, and 140. Here, a reference capacity may refer to a capacity of a battery, measured through a reference performance test (RPT). The reference performance test may periodically measure a lifespan or a capacity of a battery under specific temperature, specific current, and specific voltage range conditions to identify deteriorating performance of the target device. According to an example embodiment, the reference performance test may repeat charge and discharge under specific temperature and specific current conditions until the battery reaches a voltage with an SoC of 100% from a voltage with an SoC of 0%.

In operation S101, the extraction unit 210 may compare reference capacity data (C_{RPT}) of the plurality of battery cells 110, 120, 130, and 140 with measured capacity data C of the plurality of battery cells 110, 120, 130, and 140 to extract comparison data of comparing a measured capacity C of the plurality of battery cells 110, 120, 130, and 140 with a reference capacity (C_{RPT}) of the plurality of battery cells 110, 120, 130, and 140.

In operation S101, more specifically, the extraction unit 210 may extract a comparison value (C/C_{RPT}) of comparing the measured capacity C of the plurality of battery cells 110, 120, 130, and 140 with the reference capacity (C_{RPT}) of the plurality of battery cells 110, 120, 130, and 140.

In operation S101, the extraction unit 120 may generate a graph showing comparison value change with respect to temperature change of the plurality of battery cells 110, 120, 130, and 140. In operation S101, the extraction unit 120 may generate a graph showing change in comparison value (C/C_{RPT}) with respect to current change of the plurality of battery cells 110, 120, 130, and 140. In operation S101, the extraction unit 210 may analyze change in comparison value (C/C_{RPT}) with respect to temperature change of the plurality of battery cells 110, 120, 130, and 140 or current change of the plurality of battery cells 110, 120, 130, and 140 to measure a trend of change in comparison value (C/C_{RPT}) with respect to temperature change of the plurality of battery cells 110, 120, 130, and 140 or a trend of change in comparison value (C/C_{RPT}) with respect to current change of the battery.

In operation S102, the extraction unit 210 may measure a capacity change amount per cycle of the plurality of battery cells 110, 120, 130, and 140 with respect to cycle change of the plurality of battery cells 110, 120, 130, and 140. In operation S102, the extraction unit 210 may measure a capacity deterioration amount per cycle (ΔC) of the plurality of battery cells 110, 120, 130, and 140 with respect to cycle change of the plurality of battery cells 110, 120, 130, and 140.

In operation S103, the controller 220 may predict the capacity of the plurality of battery cells 110, 120, 130, and 140 based on comparison data and capacity change data. In operation S103, the controller 220 may predict capacity change of the plurality of battery cells 110, 120, 130, and 140 under reference performance test conditions based on capacity change data and a comparison value.

In operation S103, the controller 220 may multiply a reciprocal (C_{RPT}/C) of the comparison value to the capacity deterioration amount per cycle (ΔC) of the plurality of battery cells 110, 120, 130, and 140 to calculate

$$Δ C \times \frac{{C}_{RPT}}{C}$$

as a capacity change rate of the plurality of battery cells 110, 120, 130, and 140 under reference performance test conditions.

In operation S103, the controller 220 may convert a reference capacity of the plurality of battery cells into a nominal capacity of the plurality of battery cells based on the predicted capacity of the plurality of battery cells 110, 120, 130, and 140 under the reference performance test conditions to predict the capacity of the plurality of battery cells under the FEC conditions.

In operation S103, the controller 220 may multiply a value Cₙₒₘᵢₙₐₗ/C obtained by comparing the nominal capacity (Cₙₒₘᵢₙₐₗ) of the battery cells 110, 120, 130, and 140 with the measured capacity C of the plurality of battery cells 110, 120, 130, and 140 to the capacity deterioration amount per cycle (ΔC) of the plurality of battery cells 110, 120, 130, and 140 under the reference performance test conditions to calculate the capacity deterioration amount ((ΔC)_{FEC}) of the plurality of battery cells 110, 120, 130, and 140 under the FEC conditions.

In operation S103, the controller 220 may extract the capacity change pattern of the battery based on the capacity of the battery under the full equivalent cycle conditions.

In operation S103, the controller 220 may extract a graph showing a capacity change of a battery with respect to a full equivalent cycle change of the battery by collecting capacity change patterns of the battery with respect to a full equivalent cycle change of the battery.

In operation S103, the controller 220 may analyze a capacity change pattern of the plurality of battery cells 110, 120, 130, and 140 immediately after a reference performance test, a normal capacity change pattern of the plurality of battery cells 110, 120, 130, and 140, and a rapid capacity deterioration pattern of the plurality of battery cells 110, 120, 130, and 140.

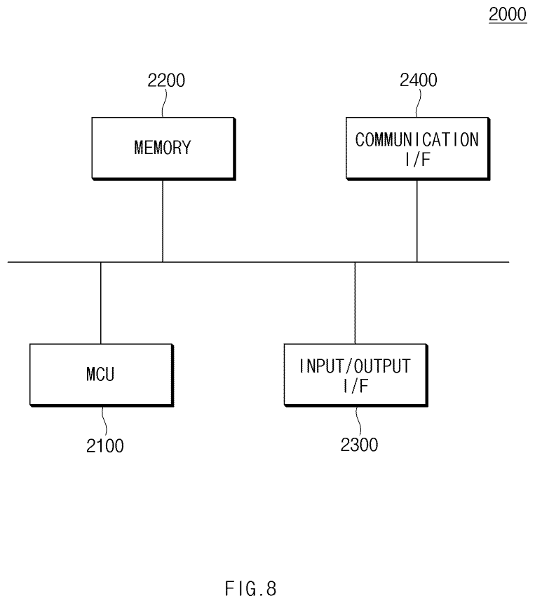

FIG. 8 is a block diagram showing a hardware configuration of a computing system for implementing a battery capacity prediction apparatus according to an example embodiment disclosed herein.

With reference to FIG. 8, a computing system 2000 according to an example embodiment disclosed herein may include an MCU 2100, a memory 2200, an input/output I/F 2300, and a communication I/F 2400.

The MCU 2100 may be a processor that executes various programs (e.g., a battery capacity prediction function, etc.) stored in the memory 2200, processes various data through these programs, and perform the above-described functions of the battery capacity prediction apparatus 200 shown in FIG. 1.

The memory 2200 may store various programs regarding operations of the battery capacity prediction apparatus. Moreover, the memory 2200 may store operation data of the battery capacity prediction apparatus 200.

The memory 2200 may be provided in plural, depending on a need. The memory 2200 may be volatile memory or non-volatile memory. For the memory 2200 as the volatile memory, random access memory (RAM), dynamic RAM (DRAM), static RAM (SRAM), etc., may be used. For the memory 2200 as the nonvolatile memory, read only memory (ROM), programmable ROM (PROM), electrically alterable ROM (EAROM), erasable PROM (EPROM), electrically erasable PROM (EEPROM), flash memory, etc., may be used. The above-listed examples of the memory 2200 are merely examples and are not limited thereto.

The input/output I/F 2300 may provide an interface for transmitting and receiving data by connecting an input device (not shown) such as a keyboard, a mouse, a touch panel, etc., and an output device such as a display (not shown), etc., to the MCU 2100.

The communication I/F 2400, which is a component capable of transmitting and receiving various data to and from a server, may be various devices capable of supporting wired or wireless communication. For example, a program for resistance measurement and abnormality diagnosis of the battery cell or various data may be transmitted and received to and from a separately provided external server through the communication I/F 2400.

As such, a computer program according to an example embodiment disclosed herein may be recorded in the memory 2200 and processed by the MCU 2100, thus being implemented as a module that performs respective functions of the battery capacity prediction apparatus 200 shown in FIGS. 1 and 2.

The above description is merely illustrative of the technical idea of the present disclosure, and various modifications and variations will be possible without departing from the essential characteristics of the present disclosure by those of ordinary skill in the art to which the present disclosure pertains.

Therefore, the example embodiments disclosed in the present disclosure are intended for description rather than limitation of the technical spirit of the present disclosure and the scope of the technical spirit of the present disclosure is not limited by these example embodiments. The protection scope of the present disclosure should be interpreted by the following claims, and all technical spirits within the same range should be understood to be included in the range of the present disclosure.

1. A battery capacity prediction apparatus, comprising:
a capacity data extractor configured to extract comparison data obtained by comparing a measured capacity of a battery with a reference capacity of the battery and to extract capacity change data obtained by measuring a capacity change of the battery with respect to a cycle change of the battery; and
a controller configured to predict a capacity of the battery based on the comparison data and the capacity change data.

2. The battery capacity prediction apparatus of claim 1, wherein the capacity data extractor is further configured to extract a comparison value obtained by comparing the measured capacity of the battery with the reference capacity of the battery, measured through a reference performance test (RPT).

3. The battery capacity prediction apparatus of claim 2, wherein the capacity data extractor is further configured to measure a change in the comparison value with respect to a temperature change of the battery or a change in the comparison value with respect to a current change of the battery.

4. The battery capacity prediction apparatus of claim 3, wherein the controller is further configured to predict the capacity of the battery under reference performance test conditions based on the capacity change data and the comparison value.

5. The battery capacity prediction apparatus of claim 1, wherein the controller is further configured to predict the capacity of the battery under full equivalent cycle (FEC) conditions by converting the reference capacity into a nominal capacity of the battery.

6. The battery capacity prediction apparatus of claim 5, wherein the controller is further configured to extract a capacity change pattern of the battery based on the capacity of the battery under the full equivalent cycle conditions.

7. The battery capacity prediction apparatus of claim 6, wherein the controller is further configured to analyze the capacity change pattern immediately after a reference performance test, a normal capacity change pattern, and a rapid capacity deterioration pattern by extracting the capacity change pattern of the battery to predict the capacity of the battery.

8. An operating method of a battery capacity prediction apparatus, the operating method comprising:
extracting comparison data by comparing a measured capacity of a battery with a reference capacity of the battery;
measuring a capacity change data of the battery with respect to a cycle change of the battery; and
predicting a capacity of the battery based on the comparison data and the capacity change data.

9. The operating method of claim 8, wherein the extracting of the comparison data comprises extracting a comparison value obtained by comparing the measured capacity of the battery with the reference capacity of the battery, measured through a reference performance test (RPT).

10. The operating method of claim 9, wherein the extracting of the comparison data comprises measuring a change in the comparison value with respect to a temperature change of the battery or a change in the comparison value with respect to a current change of the battery.

11. The operating method of claim 10, wherein the predicting of the capacity of the battery comprises predicting the capacity of the battery under reference performance test conditions based on the capacity change data and the comparison value.

12. The operating method of claim 8, wherein the predicting of the capacity of the battery comprises predicting the capacity of the battery under full equivalent cycle (FEC) conditions by converting the reference capacity into a nominal capacity of the battery.

13. The operating method of claim 12, wherein the predicting of the capacity of the battery further comprises extracting a capacity change pattern of the battery based on the capacity of the battery under the full equivalent cycle conditions.

14. The operating method of claim 13, wherein the predicting of the capacity of the battery further comprises analyzing the capacity change pattern immediately after a reference performance test, a normal capacity change pattern, and a rapid capacity deterioration pattern by extracting the capacity change pattern of the battery to predict the capacity of the battery.

15. A battery pack, comprising the battery capacity prediction apparatus of claim 1 and the battery.

16. The battery pack of claim 15, further comprising:
a relay connected between the battery and a terminal of the battery pack,
wherein the battery capacity prediction apparatus is configured to control the relay to control charging or discharging of the battery.

17. The battery capacity prediction apparatus of claim 1, wherein the controller is further configured to control charging or discharging of the battery based on the predicted capacity of the battery.

18. The operating method of claim 8, further comprising controlling charging or discharging of the battery based on the predicted capacity of the battery.
